(19) United States
(12) Patent Application Publication
(10) Pub. No.: US 2026/0018514 A1
(43) Pub. Date: Jan. 15, 2026

(54) GATE INTERCONNECTING STRUCTURES FOR STACKED FIELD-EFFECT TRANSISTORS

(71) Applicant: International Business Machines Corporation, Armonk, NY (US)

(72) Inventors: Shay Reboh, Guilderland, NY (US); Albert Manhee Chu, Nashua, NH (US); Junli Wang, Slingerlands, NY (US); James P. Mazza, Saratoga Springs, NY (US)

(21) Appl. No.: 18/770,164

(22) Filed: Jul. 11, 2024

(51) Int. Cl. H01L 23/528; H01L 23/522; H01L 27/06; H01L 27/092; H01L 29/06; H01L 29/423; H01L 29/775; H01L 29/786

(52) U.S. Cl. CPC H01L 23/5283; H01L 23/5226; H10D 30/43; H10D 30/6735; H10D 30/6757; H10D 62/121; H10D 84/856; H10D 88/00

(57) ABSTRACT

A semiconductor device comprises a first transistor structure comprising a first gate region and a second gate region, a first dielectric layer disposed between the first gate region and the second gate region, a second transistor structure stacked on the first transistor structure and comprising a third gate region and a fourth gate region, and a second dielectric layer disposed between the third gate region and the fourth gate region. A conductive via is disposed through at least one of the first dielectric layer and the second dielectric layer, wherein at least one of the first gate region and the second gate region are electrically connected to at least one of the third gate region and the fourth gate region by the conductive via.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming gate interconnecting structures for stacked FETs.

In one embodiment, a semiconductor device comprises a first transistor structure comprising a first gate region and a second gate region, a first dielectric layer disposed between the first gate region and the second gate region, a second transistor structure stacked on the first transistor structure and comprising a third gate region and a fourth gate region, and a second dielectric layer disposed between the third gate region and the fourth gate region. A conductive via is disposed through at least one of the first dielectric layer and the second dielectric layer, wherein at least one of the first gate region and the second gate region are electrically connected to at least one of the third gate region and the fourth gate region by the conductive via.

In another embodiment, a semiconductor device includes a first device layer comprising a first dielectric layer disposed between a first gate region and a second gate region, a second device layer stacked on the first device layer and comprising a second dielectric layer disposed between a third gate region and a fourth gate region, and a conductive via disposed in at least one of the first dielectric layer and the second dielectric layer. At least one of the first gate region and the second gate region are electrically connected to at least one of the third gate region and the fourth gate region through the conductive via.

In another embodiment, a semiconductor device includes a first dielectric layer disposed between a first set of two gate regions, a second dielectric layer disposed between a second set of two gate regions, wherein the second set of two gate regions are stacked on the first set of two gate regions, and a contact structure disposed in at least one of the first dielectric layer and the second dielectric layer. At least one gate region of the first set of two gate regions is electrically connected to at least one other gate region of the second set of two gate regions through the contact structure.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure taken along a gate structure following formation of a bottom level of transistors and dielectric layers separating gate regions, according to an embodiment of the invention.

FIG. 2 depicts a cross-sectional view of a semiconductor structure taken along a gate structure following formation of an opening for a bottom level contact portion, according to an embodiment of the invention.

FIG. 3 depicts a cross-sectional view of a semiconductor structure taken along a gate structure following formation of a bottom level contact portion, according to an embodiment of the invention.

FIG. 4 depicts a cross-sectional view of a semiconductor structure taken along a gate structure following formation of a top level of transistors and dielectric layers separating gate regions, according to an embodiment of the invention.

FIG. 5 depicts a cross-sectional view of a semiconductor structure taken along a gate structure following formation of an opening for a conductive via, according to an embodiment of the invention.

FIG. 6 depicts a cross-sectional view of a semiconductor structure taken along a gate structure following formation of a conductive via, according to an embodiment of the invention.

FIG. 7 depicts a cross-sectional view of a semiconductor structure taken along a gate structure following formation of an opening for a top level contact portion, according to an embodiment of the invention.

FIG. 8 depicts a cross-sectional view of a semiconductor structure taken along a gate structure following formation of a top level contact portion, according to an embodiment of the invention.

FIG. 9 depicts a cross-sectional view of a semiconductor structure taken along a gate structure following frontside inter-layer dielectric (ILD) layer deposition, frontside contact formation and frontside interconnect formation, according to an embodiment of the invention.

FIG. 10 depicts a cross-sectional view of a semiconductor structure taken along a gate structure illustrating alternative configurations of top level and bottom level contact portions, according to embodiments of the invention.

FIG. 11 depicts a cross-sectional view of a semiconductor structure taken along a gate structure following formation of an opening for an alternative top level contact portion, according to an embodiment of the invention.

FIG. 12 depicts a cross-sectional view of a semiconductor structure taken along a gate structure following formation of an alternative top level contact portion, frontside ILD layer deposition, frontside contact formation and frontside interconnect formation, according to an embodiment of the invention.

FIG. 13 depicts a cross-sectional view of a semiconductor structure taken along a gate structure following formation of a bottom level of transistors and dielectric layers separating gate regions, according to an embodiment of the invention.

FIG. 14 depicts a cross-sectional view of a semiconductor structure taken along a gate structure following formation of a top level of transistors and dielectric layers separating gate regions, according to an embodiment of the invention.

FIG. 15 depicts a cross-sectional view of a semiconductor structure taken along a gate structure following formation of an opening for a top level conductive via, according to an embodiment of the invention.

FIG. 16 depicts a cross-sectional view of a semiconductor structure taken along a gate structure following formation of a top level conductive via, according to an embodiment of the invention.

FIG. 17 depicts a cross-sectional view of a semiconductor structure taken along a gate structure following formation of an opening for a top level contact portion, according to an embodiment of the invention.

FIG. 18 depicts a cross-sectional view of a semiconductor structure taken along a gate structure following formation of a top level contact portion, according to an embodiment of the invention.

FIG. 19 depicts a cross-sectional view of a semiconductor structure taken along a gate structure following frontside ILD layer deposition, frontside contact formation and frontside interconnect formation, according to an embodiment of the invention.

FIG. 20 depicts a cross-sectional view of a semiconductor structure taken along a gate structure following wafer flipping, semiconductor substrate removal, etch stop layer removal, dielectric layer removal and formation of an opening for a bottom level conductive via, according to an embodiment of the invention.

FIG. 21 depicts a cross-sectional view of a semiconductor structure taken along a gate structure following formation of a bottom level conductive via, according to an embodiment of the invention.

FIG. 22 depicts a cross-sectional view of a semiconductor structure taken along a gate structure following formation of an opening for a bottom level contact portion, according to an embodiment of the invention.

FIG. 23 depicts a cross-sectional view of a semiconductor structure taken along a gate structure following formation of a bottom level contact portion, according to an embodiment of the invention.

FIG. 24 depicts a cross-sectional view of a semiconductor structure taken along a gate structure following backside ILD layer deposition, backside contact formation and backside interconnect formation, according to an embodiment of the invention.

FIG. 25 depicts a cross-sectional view of a semiconductor structure taken along a gate structure illustrating alternative configurations of top level and bottom level contact portions, according to embodiments of the invention.

FIG. 26 depicts a cross-sectional view of a semiconductor structure taken along a gate structure following formation of a bottom level of transistors, a top level of transistors staggered with respect to the bottom level of transistors and dielectric layers separating gate regions, according to an embodiment of the invention.

FIG. 27 depicts a cross-sectional view of a semiconductor structure taken along a gate structure following top level contact via formation, top level contact portion formation, frontside ILD layer deposition, frontside contact formation and frontside interconnect formation, according to an embodiment of the invention.

FIG. 28 depicts a cross-sectional view of a semiconductor structure taken along a gate structure following bottom level contact via formation, bottom level contact portion formation, backside ILD layer deposition, backside contact formation and backside interconnect formation, according to an embodiment of the invention.

FIG. 29 depicts a cross-sectional view of a semiconductor structure taken along a gate structure following top level contact via formation, frontside ILD layer deposition, frontside contact formation and frontside interconnect formation, according to an embodiment of the invention.

### DETAILED DESCRIPTION

Illustrative embodiments of the invention may be described herein in the context of illustrative methods for forming gate interconnecting structures for stacked FETs, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 3 to 20 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to area reduction (e.g., such as 30-40% area reduction for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

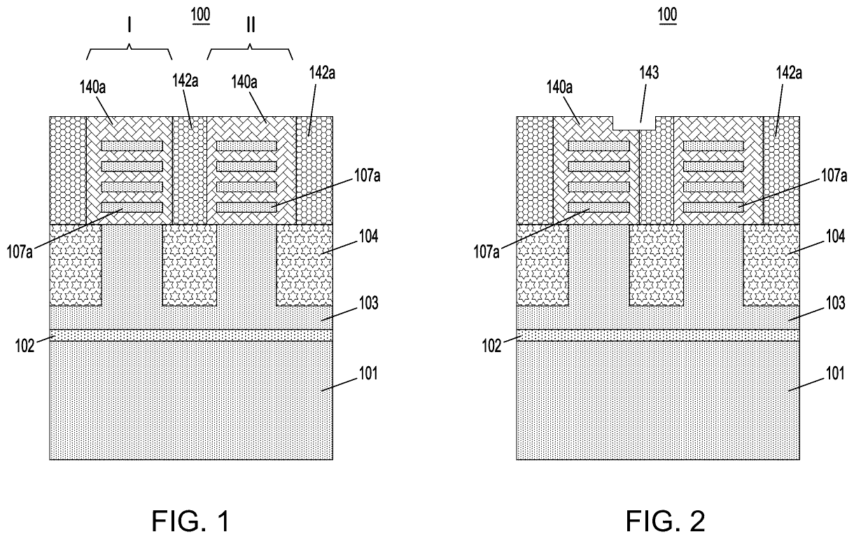

The cross-sectional views in FIGS. 1-27 are taken along a gate structure (e.g., along a gate length) and illustrate gate lengths and channel lengths in the left-to-right directions.

FIG. 1 depicts a cross-sectional view of a semiconductor structure 100 following formation of a bottom level of transistors and dielectric layers separating gate regions. The semiconductor structure 100 includes a stacked structure of a plurality of lower transistors (also referred to herein as “first transistors”). The lower transistors include nanosheet transistors. For example, the lower transistors include a plurality of first channel layers 107a alternately stacked with and surrounded by first gate structures 140a. The embodiments are not necessarily limited to the shown number of first channel layers 107a, and there may be more or less layers in the same alternating configuration depending on design constraints with the first gate structures 140a.

A first semiconductor substrate 101 and a second semiconductor substrate 103 include semiconductor material including, but not limited to, silicon, III-V, II-V compound semiconductor materials or other like semiconductor materials. In addition, multiple layers of the semiconductor materials can be used as the semiconductor material of the first and second semiconductor substrates 101 and 103. An etch stop layer 102 may be formed on the first semiconductor substrate 101 between the first semiconductor substrate 101 and the second semiconductor substrate 103. In an illustrative embodiment, the etch stop layer 102 includes silicon germanium (SiGe) with, for example, a germanium concentration of about 30% (e.g., SiGe30) or SiO₂ and the first and second semiconductor substrates 101 and 103 include silicon.

According to one or more embodiments, the etch stop layer 102 is epitaxially grown on the first semiconductor substrate 101, the second semiconductor substrate 103 is epitaxially grown on the etch stop layer 102. The etch stop layer 102 functions as an etch stop when removing the first semiconductor substrate 101 in connection with backside contact processing and/or backside power rail formation. As used herein, “frontside refers to a side on top of the second semiconductor substrate 103 and/or in front of, on top of or in an upward direction from the stacked nanosheet/gate and channel layers of the transistors in the orientation shown in the cross-sectional figures. As used herein, “backside” refers to a side below the second semiconductor substrate 103 and/or behind, under, below or in a downward direction from the stacked nanosheet/gate and channel layers of the transistors in the orientation shown in the cross-sectional figures (e.g., opposite the “frontside”).

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermanc, dichlorogermane, trichlorogermanc, tetrachlorogermane and combinations thereof. The temperature for epitaxial deposition typically ranges from 450° C. to 900° C. Although higher temperature typically results in faster deposition, the faster deposition may result in crystal defects and film cracking.

Isolation regions 104 (e.g., shallow trench isolation (STI)) regions are formed between nanosheet stacks in recessed portions of the second semiconductor substrate 103. Isolation regions 104 including dielectric material fill in the recessed portions of the second semiconductor substrate 103. The dielectric material may include, for example, SiO₂, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

The first gate structures 140a, include, for example, metal gate portions and dielectric portions. In illustrative embodiments, each first gate structure 140a includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the metal gate portion of the each first gate structure 140a includes a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Portions of the first gate structures 140a are removed where gate isolation regions (also referred to herein as “gate cut portions”) are to be formed. First gate isolation regions 142a are formed through portions of the first gate structures 140a over isolation regions 104. The first gate isolation regions 142a respectively include a dielectric layer including, for example, a nitride material (e.g., SiN, SiON, SiCN, BN, SiBN, SiBCN and/or SiOCN). The dielectric material of the first gate isolation regions 142a is deposited using deposition techniques such as, for example, CVD, PECVD, RFCVD, PVD, ALD, MBD, PLD, and/or LSMCD, followed by a planarization process, such as, chemical mechanical planarization (CMP). The first gate isolation regions 142a divide the first gate structures 140a into gate regions (e.g., gate regions I and II). Gate isolation regions described herein (including first gate isolation regions 142a) may be formed before or after replacement metal gate (RMG) processing.

Referring to FIG. 2, portions of a first gate isolation region 142a and of an adjacent first gate structure 140a are removed to create an opening 143 where a contact portion will be formed. In an illustrative embodiment, organic planarization layers (OPLs) (not shown) are deposited on portions of the first gate structures 140a and first gate isolation regions 142a. The OPLs comprise, but are not necessarily limited to, an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Alternatively, a hard mask (not shown) of one or more oxide or nitride layers is formed on portions of the first gate structures 140a and first gate isolation regions 142a, and an OPL is formed on top of the hard mask. A photoresist is used to pattern the OPL, and the patterned OPL is used to pattern the hard mask. After patterning the hard mask, portions of the first gate isolation region 142a and of the adjacent first gate structure 140a are exposed.

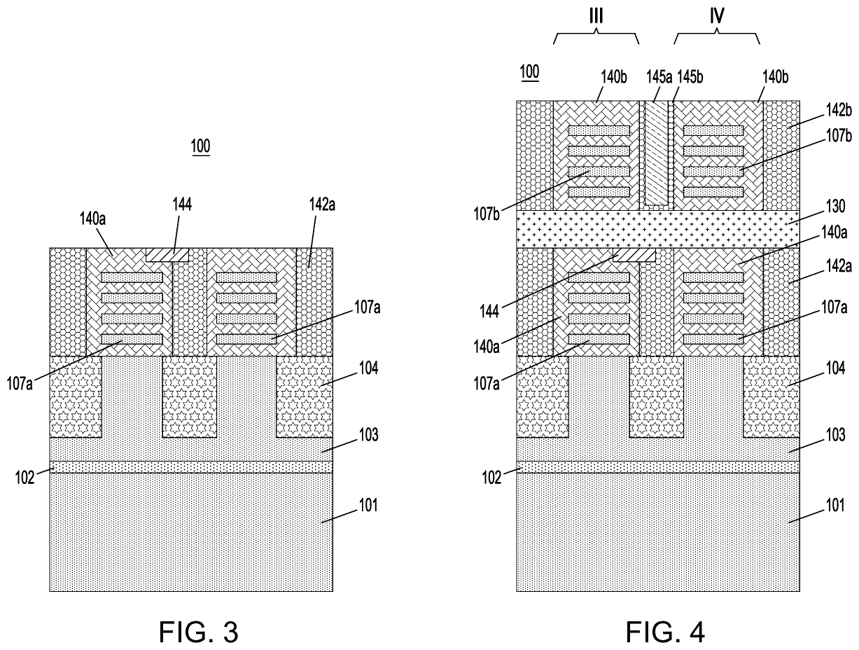

Exposed parts of the first gate structure 140a and the first gate isolation region 142a are removed to create the opening 143. The removal of the parts of a first gate structure 140a and a first gate isolation region 142a to form the opening 143 is performed using, for example, a dry etching process using a reactive ion etching (RIE) process. Referring to FIG. 3, in order to form a bottom level contact portion 144, metal is deposited to fill in the opening 143, followed by a CMP process. The deposition of the metal material in the opening 143 is performed using one or more deposition techniques such as, for example, CVD, PECVD, RFCVD, PVD, ALD, MBD, PLD, and/or LSMCD. The material of the bottom level contact portion 144 includes, for example, tungsten, cobalt, zirconium, tantalum, titanium, aluminum, ruthenium, and/or copper. The bottom level contact portion 144 forms a metal strap that provides a metal connection of an adjacent gate region to a gate cut portion. As explained in more detail in connection with FIG. 10, the bottom level contact portion 144 and other contact portions described herein below can have different configurations so that different adjacent gate regions (e.g., gate region I or gate region II) or multiple adjacent gate regions (e.g., gate region I and gate region II) are contacted.

Referring to FIG. 4, in the semiconductor structure 100, a first inter-layer dielectric (ILD) layer 130 is deposited on top of first gate structures 140a, the first gate isolation regions 142a and the bottom level contact portion 144. The first ILD layer 130 is deposited using deposition techniques such as, for example, CVD, PECVD, RFCVD, PVD, ALD, MBD, PLD, and/or LSMCD, followed by a planarization process, such as, CMP. The first ILD layer 130 may include, for example, SiOₓ, SiOC, SiOCN or some other dielectric. Alternatively, the planarization is performed before the deposition of the first ILD layer 130.

A top level of transistors similar to the bottom level of transistors is formed on the first ILD layer 130. In more detail, a plurality of upper transistors (also referred to herein as “second transistors”) include nanosheet transistors. For example, the upper transistors include a plurality of second channel layers 107b alternately stacked with and surrounded by second gate structures 140b. The embodiments are not necessarily limited to the shown number of second channel layers 107b, and there may be more or less layers in the same alternating configuration depending on design constraints with the second gate structures 140b. The top level of transistors is aligned with the bottom level of transistors.

The second gate structures 140b, include, for example, metal gate portions and dielectric portions. In illustrative embodiments, each second gate structure 140b includes a gate dielectric layer such as, for example, a high-K dielectric layer including the same or similar materials as those of the gate dielectric layers for the first gate structures 140a. According to an embodiment, like the first gate structures 140a, the metal gate portion of each second gate structure 140b includes a WFM layer, which can be deposited on the gate dielectric layer, and a gate metal layer deposited on the WFM layer and the gate dielectric layer. The WFM and gate metal layers of the second gate structures 140b include the same or similar materials as those of the WFM and gate metal layers of the first gate structures 140a.

Like with the first gate structures 140a, portions of the second gate structures 140b are removed where gate isolation regions (also referred to herein as “gate cut portions”) are to be formed. Second gate isolation regions 142b are formed through portions of the second gate structures 140b over the first gate isolation regions 142a. The second gate isolation regions 142b respectively include a dielectric layer including, for example, the same material as the first gate isolation regions 142a and are deposited using the same deposition techniques as the first gate isolation regions 142a, followed by a planarization process, such as, CMP. As noted hereinabove, gate isolation regions described herein (including second gate isolation regions 142b) may be formed before or after RMG processing.

As can be seen in FIG. 4, a gate cut portion formed over the first gate isolation region 142a in which the bottom level contact portion 144 is formed may include a bi-layer of dielectric material. The bi-layer comprises a central dielectric layer 145a and liner dielectric layer 145b. In illustrative embodiments, the liner dielectric layer 145b comprises the same material as the first and second gate isolation regions 142a and 142b. The central dielectric layer 145a comprises a material that can be selectively removed with respect to a material of the liner dielectric layer 145b such as, for example, an oxide when the liner dielectric layer 145b comprises, for example, a nitride. The liner dielectric layer 145b is a continuous layer on sides of and underneath the central dielectric layer 145a. The portion of the liner dielectric layer 145b under the central dielectric layer 145a connects the two vertical portions of liner dielectric layer 145b. The second gate isolation regions 142b and bi-layer comprising the central dielectric layer 145a and liner dielectric layer 145b divide the second gate structures 140b into gate regions (e.g., gate regions III and IV).

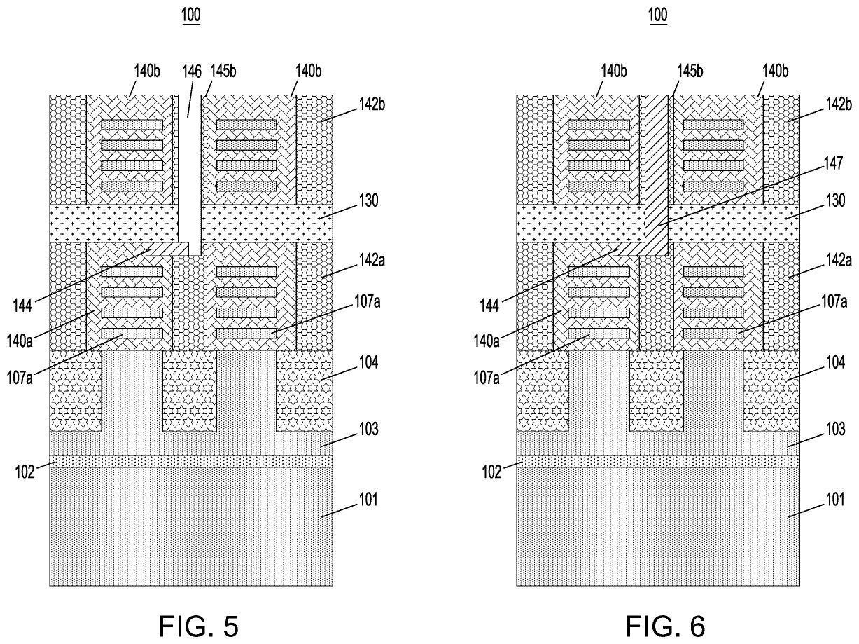

Referring to FIG. 5, the central dielectric layer 145a and underlying portions of the liner dielectric layer 145b, first ILD layer 130 and first gate isolation region 142a adjacent the bottom level contact portion 144 are etched to form an opening 146. As can be seen, portions of the liner dielectric layer 145b that are on sides of the second gate structures 140b, and portions of first gate isolation region 142a that are on a side of a first gate structure 140a are not removed. The etching may comprise, for example, an RIE process using patterned hard masks. Referring to FIG. 6, in order to form a conductive via 147, metal is deposited to fill in the opening 146, followed by a CMP process. The deposition of the metal material in the opening 146 is performed using one or more deposition techniques such as, for example, CVD, PECVD, RFCVD, PVD, ALD, MBD, PLD, and/or LSMCD. The material of the conductive via 147 includes, for example, tungsten, cobalt, zirconium, tantalum, titanium, aluminum, ruthenium, and/or copper. As can be seen in FIG. 6, the conductive via 147 contacts the bottom level contact portion 144, which, in turn, contacts a first gate structure (e.g., gate region I).

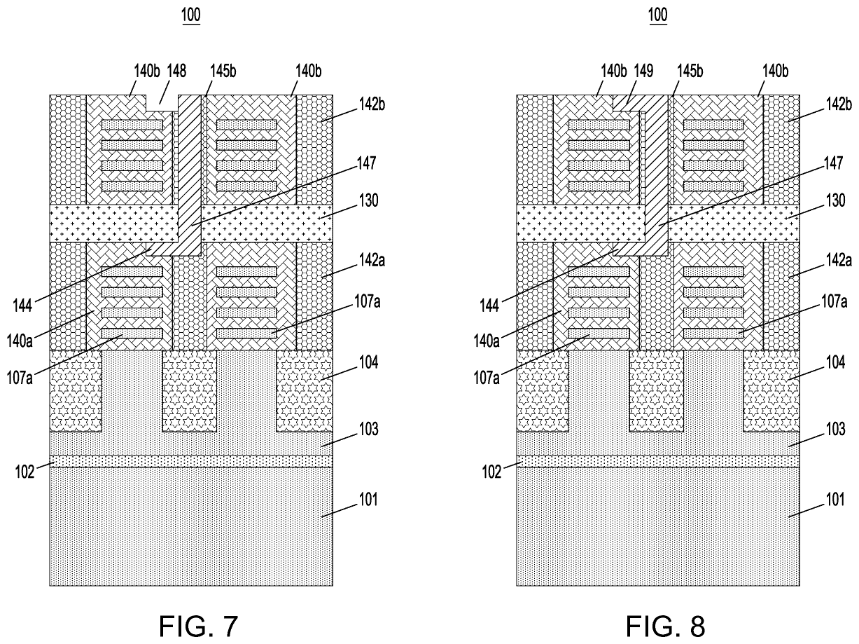

Referring to FIG. 7, portions of the liner dielectric layer 145b and of an adjacent second gate structure 140b are removed to create an opening 148 where a contact portion will be formed. In an illustrative embodiment, similar to the creation of the opening 143, OPLs (not shown) or a combination of OPLs and hard masks (not shown) are deposited on portions of the second gate structures 140b, conductive via 147, liner dielectric layer 145b and second gate isolation regions 142b. Exposed parts of a liner dielectric layer 145b and a second gate structure 140b are removed to create the opening 148. The removal of the parts of a second gate structure 140b and a liner dielectric layer 145b to form the opening 148 is performed using, for example, RIE. Referring to FIG. 8, in order to form a top level contact portion 149, metal is deposited to fill in the opening 148, followed by a CMP process. The deposition of the metal material in the opening 148 is performed using one or more deposition techniques such as, for example, CVD, PECVD, RFCVD, PVD, ALD, MBD, PLD, and/or LSMCD. The material of the top level contact portion 149 includes, for example, tungsten, cobalt, zirconium, tantalum, titanium, aluminum, ruthenium, and/or copper. The top level contact portion 149 forms a metal strap that provides a metal connection of an adjacent gate region to a gate cut portion. As explained in more detail in connection with FIG. 10, the top level contact portion 149 and other contact portions described herein below can have different configurations so that different adjacent gate regions (e.g., gate region III or gate region IV) or multiple adjacent gate regions (e.g., gate region III and gate region IV) are contacted.

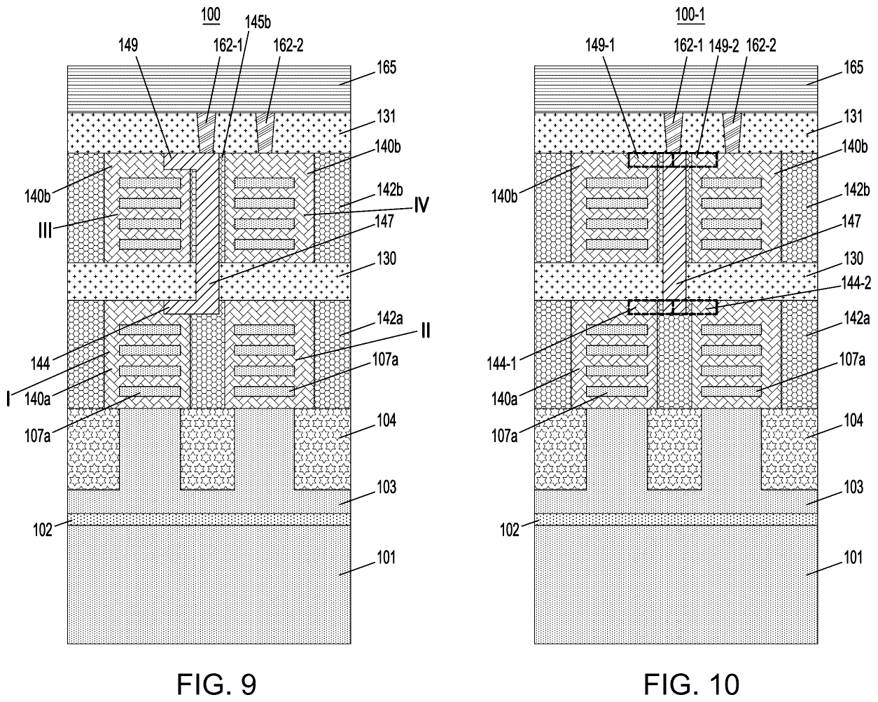

Referring to FIG. 9, additional ILD material is deposited to form a second ILD layer 131 on top of the second gate structures 140b, the second gate isolation regions 142b, the top level contact portion 149, the conductive via 147 and the liner dielectric layer 145b. The second ILD layer 131 is deposited using deposition techniques such as, for example, CVD, PECVD, RFCVD, PVD, ALD, MBD, PLD, and/or LSMCD, followed by a planarization process, such as, CMP. The second ILD layer 131 may include, for example, SiOₓ, SiOC, SiOCN or some other dielectric material. Then, first and second frontside gate contacts 162-1 and 162-2 (collectively “frontside gate contacts 162”) are formed in the second ILD layer 131. As can be seen, the first frontside gate contact 162-1 lands on and contacts the conductive via 147 (and/or top level contact portion 149, or the second gate structure 140b of gate region III, depending on a location of the first frontside gate contact 162-1) and the second frontside gate contact 162-2 lands on and contacts a second gate structure 140b (e.g., gate region IV). In forming the frontside gate contacts 162, openings are formed through portions of the second ILD layer 131. The openings expose portions of the conductive via 147 (and/or top level contact portion 149) and the second gate structure 140b on which the frontside gate contacts 162 are to be formed. According to an embodiment, masks are formed on parts of the second ILD layer 131 and exposed portions of the second ILD layer 131 corresponding to where the openings are to be formed are removed using, for example, a dry etching process using an RIE or ion beam etch (IBE) process, a wet chemical etch process or a combination of these etching processes. A dry etch may be performed using a plasma. Such wet or dry etch processes include, for example, IBE by Ar/CHF₃ based chemistry.

Metal layers including the same or similar materials as those used for the top and bottom level contact portions 149 and 144, and for the conductive via 147 are deposited in the openings to form the frontside gate contacts 162. The metal layers can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the second ILD layer 131.

Frontside BEOL interconnects 165 are formed on the second ILD layer 131 and are connected to the frontside gate contacts 162 through a plurality of wires. As can be understood, a gate voltage from the first frontside gate contact 162-1 can be delivered to the second gate structure 140b of gate region III and to the first gate structure 140a of gate region I through the top level contact portion 149, the conductive via 147 and the bottom level contact portion 144. In the semiconductor structure 100 in FIG. 9, the top level contact portion 149, the conductive via 147 and the bottom level contact portion 144 are electrically isolated from the second gate structure 140b of gate region IV by the liner dielectric layer 145b and are electrically isolated from the first gate structure 140a of gate region II by the remaining portion of the first gate isolation region 142a. The liner dielectric layer 145b is disposed on sides of the conductive via 147 between the conductive via 147 and the adjacent second gate structures 140b. The second gate structure 140b of gate region III and the first gate structure 140a of gate region I are electrically connected to each other through the top level contact portion 149, the conductive via 147 and the bottom level contact portion 144.

The conductive via 147 is disposed through the liner dielectric layer 145b, and through the first ILD layer 130. The conductive via 147 is disposed in an upper portion of the first gate isolation region 142a. The top level contact portion 149 extends perpendicularly from a top end of the conductive via 147 into the second gate structure 140b of gate region III, and the bottom level contact portion 144 extends perpendicularly from a bottom end of the conductive via 147 into the first gate structure 140a of gate region I.

FIG. 10 depicts a cross-sectional view of a semiconductor structure 100-1 taken along a gate structure and illustrates alternative configurations of top level and bottom level contact portions. The semiconductor structure 100-1 is the same as the semiconductor structure 100, except to illustrate that the top level and bottom level contact portions can have different configurations and different combinations of configurations. By way of explanation, first top level contact portion 149-1 in FIG. 10 is the same as top level contact portion 149, and first bottom level contact portion 144-1 in FIG. 10 is the same as bottom level contact portion 144. In illustrative embodiments, the semiconductor structure 100-1 can include any combination of one or more of first top level contact portion 149-1, second top level contact portion 149-2, first bottom level contact portion 144-1 and second bottom level contact portion 144-2 to electrically connect one or more gate regions I, II, III and IV to each other through the conductive via 147. By way of non-limiting example, the semiconductor structure 100-1 can include each of first top level contact portion 149-1, second top level contact portion 149-2, first bottom level contact portion 144-1 and second bottom level contact portion 144-2 so that gate regions I, II, III and IV are electrically connected to each other. In another non-limiting illustrative example, the semiconductor structure 100-1 includes the first top level contact portion 149-1, second top level contact portion 149-2 and first bottom level contact portion 144-1 so that gate regions I, III and IV are electrically connected to each other. In a further non-limiting illustrative example, the semiconductor structure 100-1 includes first top level contact portion 149-1 and second bottom level contact portion 144-2 so that gate regions III and II are electrically connected to each other. As can be understood other combinations of one or more of first top level contact portion 149-1, second top level contact portion 149-2, first bottom level contact portion 144-1 and second bottom level contact portion 144-2 are possible.

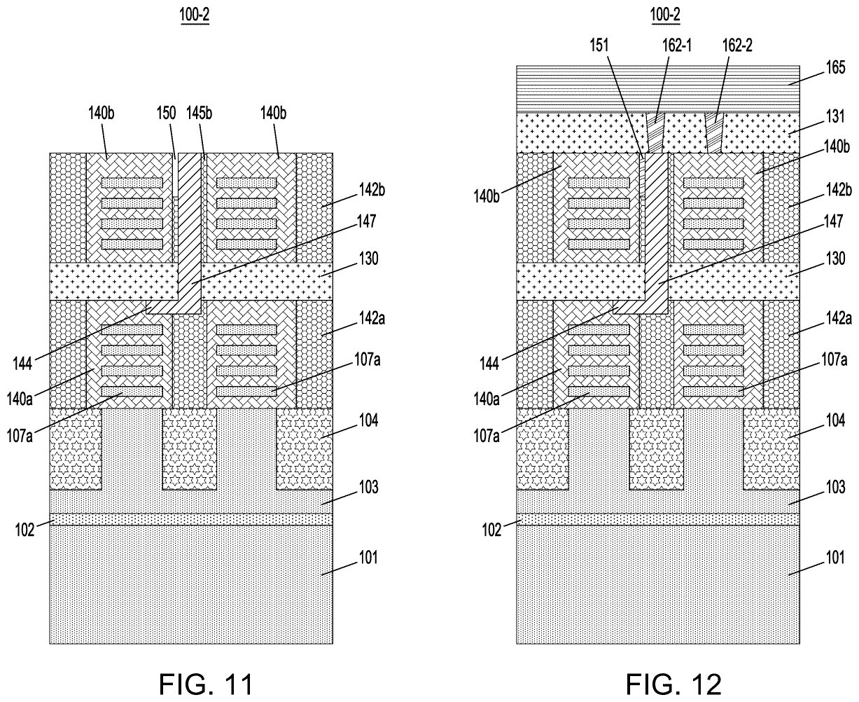

FIGS. 11 and 12 depict semiconductor structure 100-2, which includes an alternative top level contact portion 151 to be used in place of the top level contact portion 149. In other respects, the semiconductor structure 100-2 is the same as semiconductor structure 100. Referring to FIG. 11, unlike FIG. 7, instead of removing part of the second gate structure 140b and a portion of the liner dielectric layer 145b to create opening 148, only a portion of the liner dielectric layer 145b is removed to create an opening 150 exposing a side of the adjacent second gate structure 140b of gate region III. Then, referring to FIG. 12, the opening 150 is filled with metal to create the alternative top level contact portion 151. Like the top level contact portion 149, the alternative top level contact portion 151 is deposited using one or more deposition techniques such as, for example, CVD, PECVD, RFCVD, PVD, ALD, MBD, PLD, and/or LSMCD, and includes, for example, tungsten, cobalt, zirconium, tantalum, titanium, aluminum, ruthenium, and/or copper. The alternative top level contact portion 151, which is disposed between the conductive via 147 and the second gate structure 140b of gate region III, electrically connects the conductive via 147 to the second gate structure 140b of gate region III, but does not require removal of a portion of the second gate structure 140b during its formation.

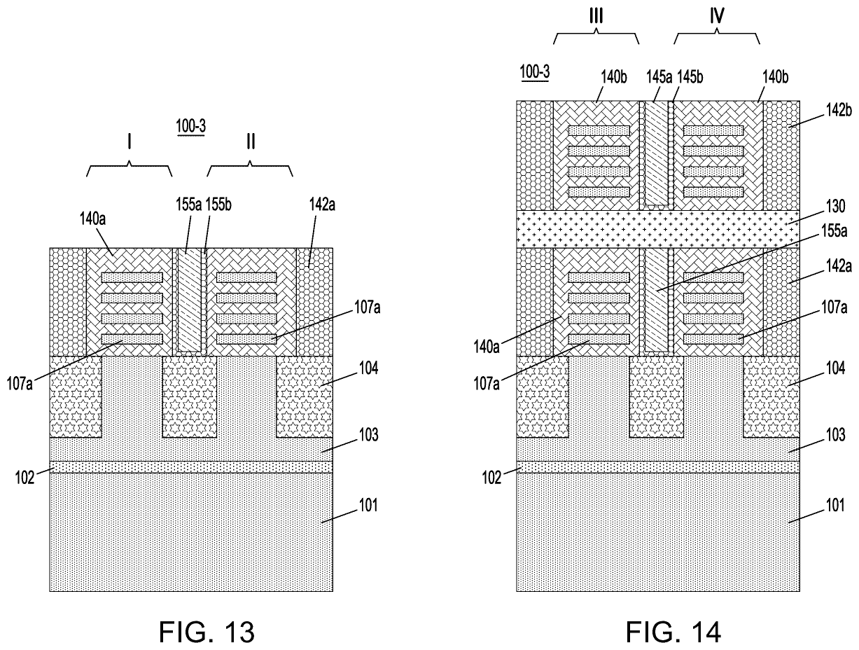

Referring to FIGS. 13-24, formation of a semiconductor structure 100-3 with an alternative conductive via configuration to that of the semiconductor structure 100 is shown. Elements the same as those in semiconductor structure 100 are depicted with the same reference numbers. Referring to FIG. 13, in the semiconductor structure 100-3, like the semiconductor structure 100, a bottom level of transistors comprises lower transistors including nanosheet transistors with first channel layers 107a alternately stacked with and surrounded by first gate structures 140a.

Portions of the first gate structures 140a are removed where gate isolation regions (also referred to herein as “gate cut portions”) are to be formed. First gate isolation regions 142a are formed through portions of the first gate structures 140a. As can be seen in FIG. 13, unlike the semiconductor structure 100, in an initial stage of fabrication, the bottom device level includes a middle gate cut portion with a bi-layer of dielectric material. In an alternative embodiment, in the semiconductor structure 100, in an initial stage of fabrication, the bottom device level can include a middle gate cut portion with a bi-layer of dielectric material instead of a single dielectric layer. The bi-layer in FIG. 13 comprises a central dielectric layer 155a and liner dielectric layer 155b. In illustrative embodiments, the liner dielectric layer 155b comprises the same material as the first gate isolation regions 142a. The central dielectric layer 155a comprises a material that can be selectively removed with respect to a material of the liner dielectric layer 155b such as, for example, an oxide when the liner dielectric layer 155b comprises, for example, a nitride. The liner dielectric layer 155b is a continuous layer on sides of and underneath the central dielectric layer 155a. The portion of the liner dielectric layer 155b under the central dielectric layer 155a connects the two vertical portions of liner dielectric layer 155b. The first gate isolation regions 142a and bi-layer comprising the central dielectric layer 155a and liner dielectric layer 155b divide the first gate structures 140a into gate regions (e.g., gate regions I and II). Unlike the semiconductor structure 100, the semiconductor structure 100-3 does not form a bottom level contact portion 144 at initial stage of fabrication (e.g., prior to formation of a top level of transistors). As noted hereinabove, gate isolation regions described herein (including first gate isolation regions 142a) may be formed before or after RMG processing.

Referring to FIG. 14, like the semiconductor structure 100, the semiconductor structure 100-3 includes the first ILD layer 130 on top of first gate structures 140a. A top level of transistors similar to the bottom level of transistors is formed on the first ILD layer 130. In more detail, a plurality of upper transistors (also referred to herein as “second transistors”) include nanosheet transistors. For example, the upper transistors include a plurality of second channel layers 107b alternately stacked with and surrounded by second gate structures 140b. The top level of transistors is aligned with the bottom level of transistors.

Like with the first gate structures 140a, portions of the second gate structures 140b are removed where gate isolation regions (also referred to herein as “gate cut portions”) are to be formed. Second gate isolation regions 142b are formed through portions of the second gate structures 140b over the first gate isolation regions 142a. The second gate isolation regions 142b respectively include a dielectric layer including, for example, the same material as the first gate isolation regions 142a and are deposited using the same deposition techniques as the first gate isolation regions 142a, followed by a planarization process, such as, CMP. As noted hereinabove, gate isolation regions described herein (including second gate isolation regions 142b) may be formed before or after RMG processing.

As can be seen in FIG. 14, a gate cut portion formed over the middle gate cut portion of the lower device level also includes a bi-layer of dielectric material. The bi-layer is similar to the bi-layer described in connection with the semiconductor structure 100 in FIG. 4, and has been numbered with the same reference numerals. In more detail, the bi-layer in the top device level comprises a central dielectric layer 145a and liner dielectric layer 145b. The second gate isolation regions 142b and bi-layer comprising the central dielectric layer 145a and liner dielectric layer 145b divide the second gate structures 140b into gate regions (e.g., gate regions III and IV).

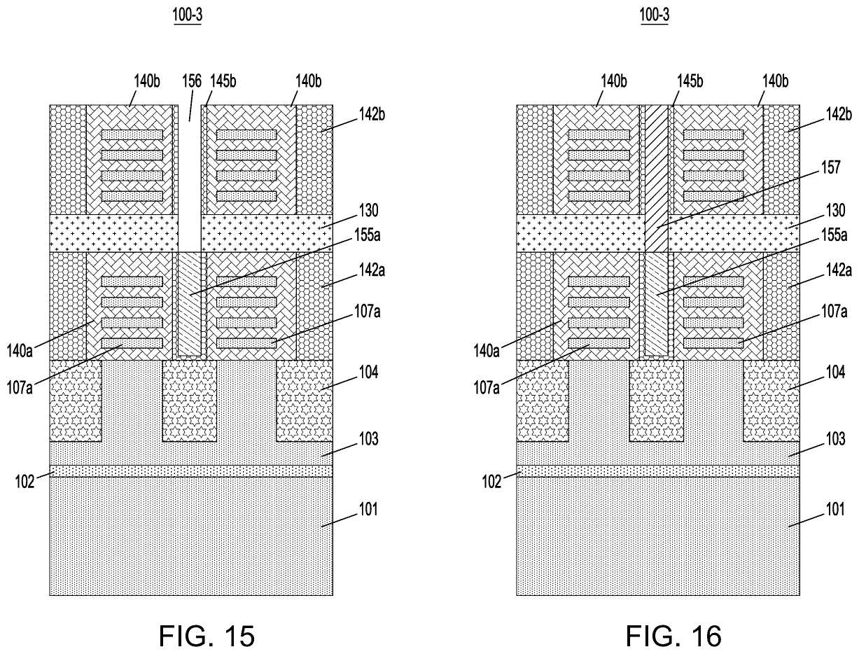

Referring to FIG. 15, the central dielectric layer 145a and underlying portions of the first ILD layer 130 are etched to form an opening 156. As can be seen, portions of the liner dielectric layer 145b that are on sides of the second gate structures 140b are not removed. The etching may comprise, for example, an RIE process. Referring to FIG. 16, in order to form a top level conductive via 157, metal is deposited to fill in the opening 156, followed by a CMP process. The deposition of the metal material in the opening 156 is performed using one or more deposition techniques such as, for example, CVD, PECVD, RFCVD, PVD, ALD, MBD, PLD, and/or LSMCD. The material of the top level conductive via 157 includes, for example, tungsten, cobalt, zirconium, tantalum, titanium, aluminum, ruthenium, and/or copper.

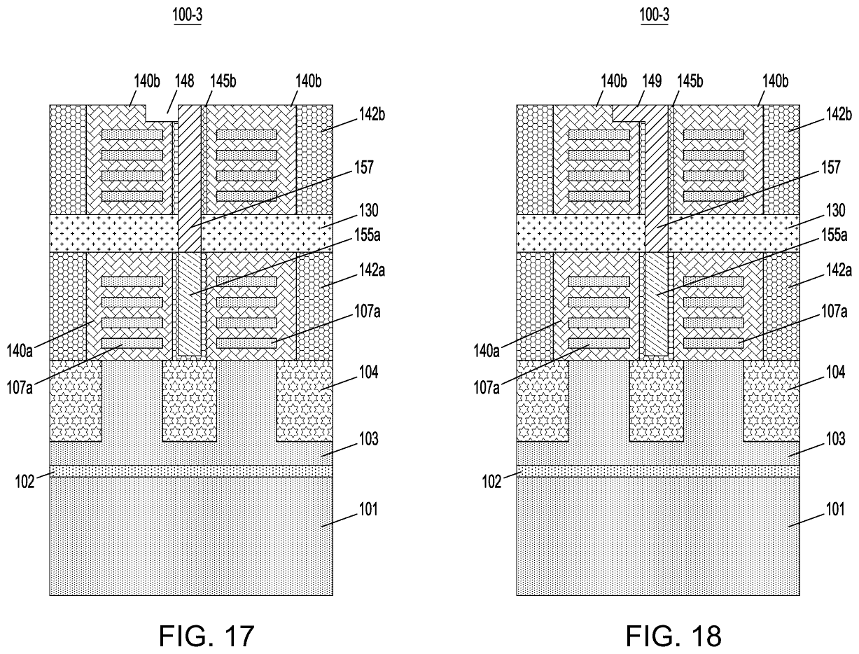

Referring to FIG. 17, like what is described in connection with the semiconductor structure 100 in FIG. 7, portions of the liner dielectric layer 145b and of an adjacent second gate structure 140b are removed to create an opening 148 where a contact portion will be formed. In an illustrative embodiment, as described herein above, OPLs (not shown) or a combination of hard mask and OPLs (not shown) are deposited on portions of the second gate structures 140b, top level conductive via 157, liner dielectric layer 145b and second gate isolation regions 142b. Exposed parts of a liner dielectric layer 145b and a second gate structure 140b are removed to create the opening 148. The removal of the parts of a second gate structure 140b and a liner dielectric layer 145b to form the opening 148 is performed using, for example, RIE. Referring to FIG. 18, like what is described in connection with the semiconductor structure 100 in FIG. 8, in order to form a top level contact portion 149, metal is deposited to fill in the opening 148, followed by a CMP process. The deposition of the metal material in the opening 148 is performed using one or more deposition techniques such as, for example, CVD, PECVD, RFCVD, PVD, ALD, MBD, PLD, and/or LSMCD. The material of the top level contact portion 149 includes, for example, tungsten, cobalt, zirconium, tantalum, titanium, aluminum, ruthenium, and/or copper. The top level contact portion 149 forms a metal strap that provides a metal connection of an adjacent gate region to a gate cut portion.

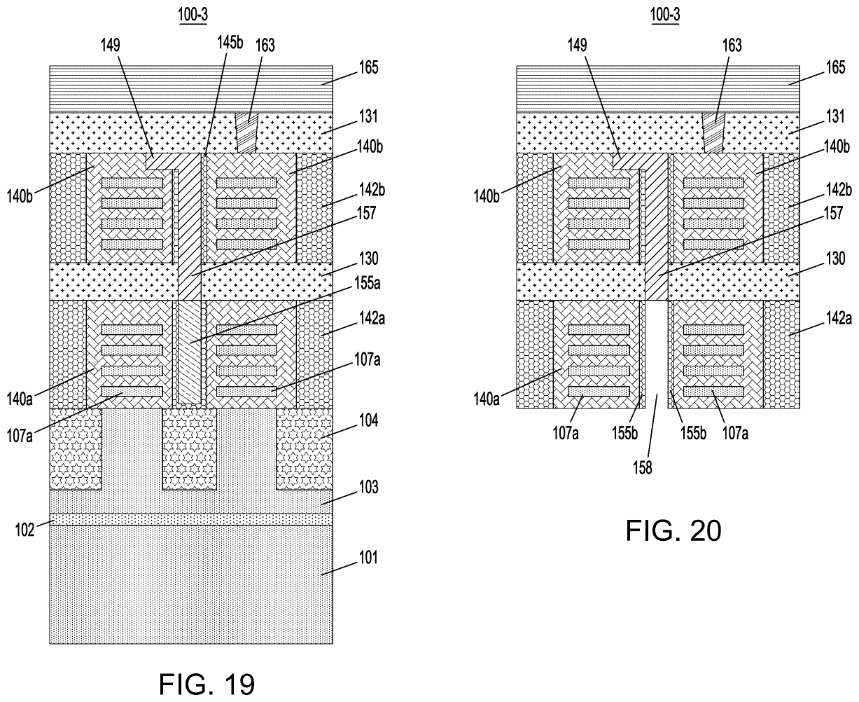

Referring to FIG. 19, additional ILD material is deposited to form a second ILD layer 131 on top of the second gate structures 140b, the second gate isolation regions 142b, the top level contact portion 149, the top level conductive via 157 and the liner dielectric layer 145b. The second ILD layer 131 is deposited using deposition techniques such as, for example, CVD, PECVD, RFCVD, PVD, ALD, MBD, PLD, and/or LSMCD, followed by a planarization process, such as, CMP. The second ILD layer 131 may include, for example, SiOₓ, SiOC, SiOCN or some other dielectric material. Then, a frontside gate contact 163, which can be the same as or similar to the second frontside gate contact 162-2 is formed in the second ILD layer 131. As can be seen, the frontside gate contact 163 lands on and contacts a second gate structure 140b (e.g., gate region IV).

Referring to FIG. 20, using a carrier wafer (not shown), the semiconductor structure 100-3 may be “flipped” (e.g., rotated 180 degrees) so that the structure is inverted. In addition, the first semiconductor substrate 101 is removed from the backside of the semiconductor structure 100-3. The removal process, which comprises etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe, with ammonia based chemistry). Then, the etch stop layer 102 and the second semiconductor substrate 103 (e.g., silicon layer) are selectively removed from the semiconductor structure 100 with respect to the isolation regions 104. The etch stop layer 102 is removed, followed by removal of the second semiconductor substrate 103, wherein portions of the isolation regions 104 are exposed. Etching processes for removal of the etch stop layer 102 include, for example hot SC1, IBE by Ar/CHF3 based chemistry. Following this, some portions of the exposed isolation regions 104 are also removed.

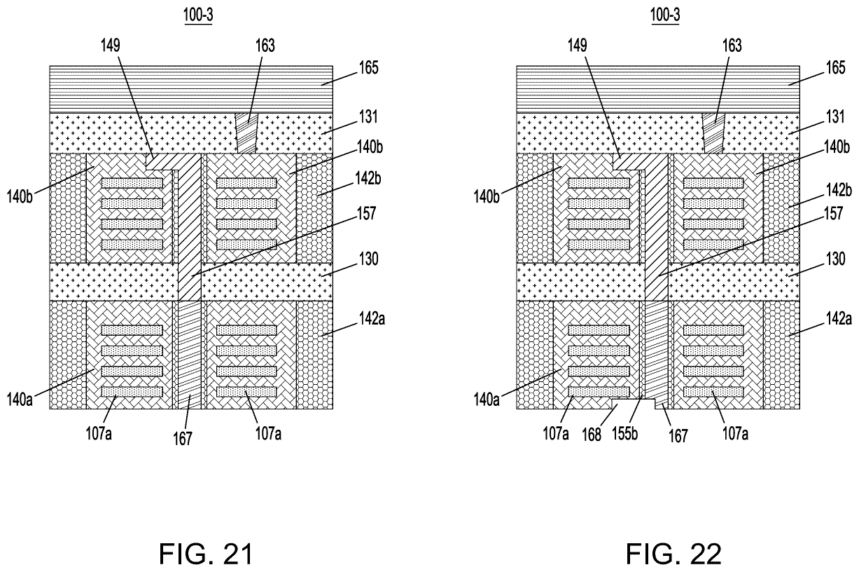

The central dielectric layer 155a is etched from the backside of the semiconductor structure 100-3 to form an opening 158 exposing a surface of the top level conductive via 157. In an illustrative embodiment, as described herein above, OPLs (not shown) or a combination of hard mask and OPLs (not shown) are deposited on portions of the first gate structures 140a, liner dielectric layer 155b and first gate isolation regions 142a. Exposed parts of a liner dielectric layer 155b and central dielectric layer 155a are removed to create the opening 158. As can be seen, portions of the liner dielectric layer 155b that are on sides of the first gate structures 140a are not removed. The etching may comprise, for example, an RIE process. Referring to FIG. 21, in order to form a bottom level conductive via 167, metal is deposited to fill in the opening 158, followed by a CMP process. The deposition of the metal material in the opening 158 is performed using one or more deposition techniques such as, for example, CVD, PECVD, RFCVD, PVD, ALD, MBD, PLD, and/or LSMCD. The material of the bottom level conductive via 167 includes, for example, tungsten, cobalt, zirconium, tantalum, titanium, aluminum, ruthenium, and/or copper. The combination of the top level conductive via 157 and the bottom level conductive via 167 forms a unitary conductive via extending through the liner dielectric layer 145b, the first ILD layer 130 and the liner dielectric layer 155b.

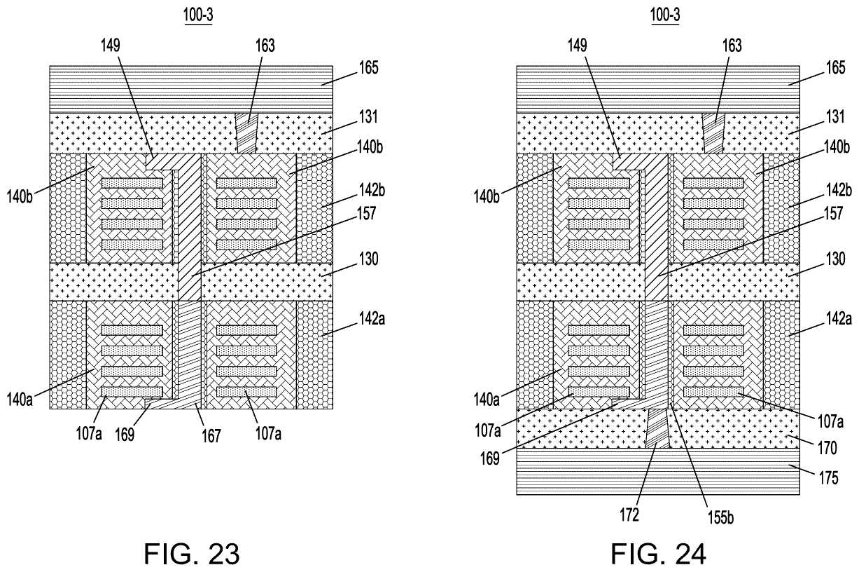

Referring to FIG. 22, portions of the liner dielectric layer 155b and of an adjacent first gate structure 140a are removed to create an opening 168 at a backside of the semiconductor structure 100-3 where a contact portion will be formed. In an illustrative embodiment, as described hereinabove, OPLs (not shown) or a combination of a hard mask and OPLs (not shown) are deposited on portions of the first gate structures 140a, bottom level conductive via 167, liner dielectric layer 155b and first gate isolation regions 142a. Exposed parts of a liner dielectric layer 155b and a first gate structure 140a are removed to create the opening 168. The removal of the parts of a first gate structure 140a and a liner dielectric layer 155b to form the opening 168 is performed using, for example, RIE. Referring to FIG. 23, in order to form a bottom level contact portion 169, metal is deposited to fill in the opening 168, followed by a CMP process. The deposition of the metal material in the opening 168 is performed using one or more deposition techniques such as, for example, CVD, PECVD, RFCVD, PVD, ALD, MBD, PLD, and/or LSMCD. The material of the bottom level contact portion 169 includes, for example, tungsten, cobalt, zirconium, tantalum, titanium, aluminum, ruthenium, and/or copper. The bottom level contact portion 169 forms a metal strap that provides a metal connection of an adjacent gate region to a gate cut portion.

Referring to FIG. 24, ILD material is deposited to form a backside ILD layer 170 on the first gate structures 140a, the first gate isolation regions 142a, the bottom level contact portion 169, the bottom level conductive via 167 and the liner dielectric layer 155b. The backside ILD layer 170 is deposited using deposition techniques such as, for example, CVD, PECVD, RFCVD, PVD, ALD, MBD, PLD, and/or LSMCD, followed by a planarization process, such as, CMP. The backside ILD layer 170 may include, for example, SiOₓ, SiOC, SiOCN or some other dielectric material. Then, at least one backside gate contact 172 is formed in the backside ILD layer 170. As can be seen, the backside gate contact 172 lands on and contacts the bottom level conductive via 167 (and/or bottom level contact portion 169 depending on a location of the backside gate contact 172. In forming the backside gate contact 172, an opening is formed through a portion of the backside ILD layer 170. The opening exposes portions of the bottom level conductive via 167 (and/or bottom level contact portion 169) on which the backside gate contact 172 is to be formed. According to an embodiment, masks are formed on parts of the backside ILD layer 170 and exposed portions of the backside ILD layer 170 corresponding to where the openings are to be formed are removed using, for example, a dry etching process using an RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers including the same or similar materials as those used for the top and bottom level contact portions 149 and 169 and top and bottom level conductive vias 157 and 167, are deposited in the opening to form the backside gate contact 172. The metal layers can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 170.

Backside interconnects 175 are formed on the backside ILD layer 170 and are connected to the backside gate contact 172 through a plurality of wires. As can be understood, a gate voltage from the backside gate contact 172 can be delivered to the first gate structure 140a of gate region I and to the second gate structure 140b of gate region III through the bottom level contact portion 169, the bottom level conductive via 167, the top level conductive via 157 and the top level contact portion 149. In the semiconductor structure 100-3 in FIG. 24, the bottom level contact portion 169, the bottom level conductive via 167, the top level conductive via 157 and the top level contact portion 149 are electrically isolated from the first gate structure 140a of gate region II by the liner dielectric layer 155b and are electrically isolated from the second gate structure 140b of gate region IV by the liner dielectric layer 145b. The liner dielectric layer 145b is disposed on sides of the top level conductive via 157 between the top level conductive via 157 and the adjacent second gate structures 140b. The liner dielectric layer 155b is disposed on sides of the bottom level conductive via 167 between the bottom level conductive via 167 and the adjacent second gate structures 140b. The second gate structure 140b of gate region III and the first gate structure 140a of gate region I are electrically connected to each other through the bottom level contact portion 169, the bottom level conductive via 167, the top level conductive via 157 and the top level contact portion 149.

The top level contact portion 149 extends perpendicularly from an end of the top level conductive via 157 into the second gate structure 140b of gate region III, and the bottom level contact portion 169 extends perpendicularly from an end of the bottom level conductive via 167 into the first gate structure 140a of gate region I.

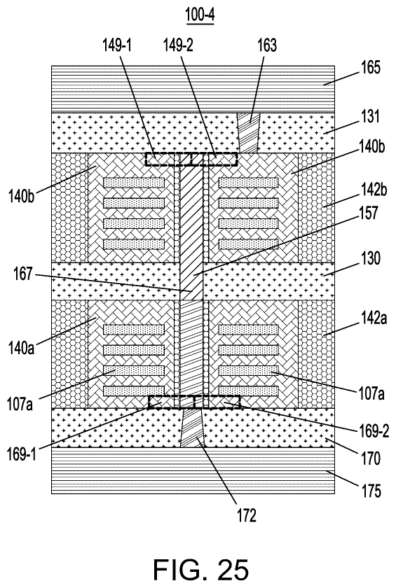

Similar to FIG. 10, FIG. 25 depicts a cross-sectional view of a semiconductor structure 100-4 taken along a gate structure and illustrates alternative configurations of top level and bottom level contact portions. The semiconductor structure 100-4 is the same as the semiconductor structure 100-3, except to illustrate that the top level and bottom level contact portions can have different configurations and different combinations of configurations. By way of explanation, first top level contact portion 149-1 in FIG. 25 is the same as top level contact portion 149, and first bottom level contact portion 169-1 in FIG. 25 is the same as bottom level contact portion 169. In illustrative embodiments, the semiconductor structure 100-4 can include any combination of one or more of first top level contact portion 149-1, second top level contact portion 149-2, first bottom level contact portion 169-1 and second bottom level contact portion 169-2 to electrically connect one or more gate regions I, II, III and IV to each other through the top level conductive via 157 and bottom level conductive via 167. By way of non-limiting example, the semiconductor structure 100-4 can include each of first top level contact portion 149-1, second top level contact portion 149-2, first bottom level contact portion 169-1 and second bottom level contact portion 169-2 so that gate regions I, II, III and IV are electrically connected to each other. In another non-limiting illustrative example, the semiconductor structure 100-4 includes the first top level contact portion 149-1, second top level contact portion 149-2 and first bottom level contact portion 169-1 so that gate regions I, III and IV are electrically connected to each other. In a further non-limiting illustrative example, the semiconductor structure 100-4 includes first top level contact portion 149-1 and second bottom level contact portion 169-2 so that gate regions III and II are electrically connected to each other. As can be understood other combinations of one or more of first top level contact portion 149-1, second top level contact portion 149-2, first bottom level contact portion 169-1 and second bottom level contact portion 169-2 are possible.

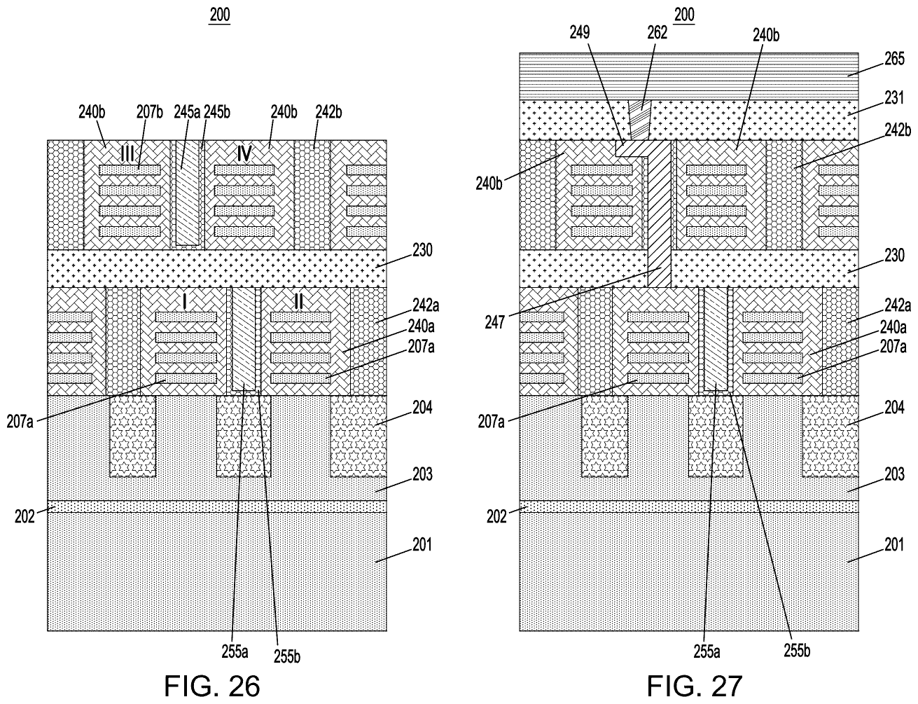

FIG. 26 depicts a cross-sectional view of a semiconductor structure 200 taken along a gate structure following formation of a bottom level of transistors, a top level of transistors staggered with respect to the bottom level of transistors and dielectric layers separating gate regions. The semiconductor structure 200 is similar to the semiconductor structure 100-3. However, unlike the semiconductor structure 100-3, in the semiconductor structure 200, a bottom level of transistors and a top level of transistors are not aligned, but are staggered with respect to each other. Similar elements in the semiconductor structure 200 have similar reference numbers to those in the semiconductor structure 100-3. For example, a first semiconductor substrate 201, an etch stop layer 202, a second semiconductor substrate 203, isolation regions 204, first and second channel layers 207a and 207b, a first ILD layer 230, first and second gate structures 240a and 240b, first and second gate isolation regions 242a and 242b, a top level bi-layer comprising a central dielectric layer 245a and liner dielectric layer 245b and a bottom level bi-layer comprising a central dielectric layer 255a and liner dielectric layer 255b of the semiconductor structure 200 are similar to the first semiconductor substrate 101, the etch stop layer 102, the second semiconductor substrate 103, isolation regions 104, first and second channel layers 107a and 107b, the first ILD layer 130, first and second gate structures 140a and 140b, first and second gate isolation regions 142a and 142b, the top level bi-layer comprising a central dielectric layer 145a and liner dielectric layer 145b and the bottom level bi-layer comprising a central dielectric layer 155a and liner dielectric layer 155b of the semiconductor structure 100-3.

Referring to FIG. 26, in the semiconductor structure 200, like the semiconductor structure 100-3, a bottom level of transistors comprises lower transistors including nanosheet transistors with first channel layers 207a alternately stacked with and surrounded by first gate structures 240a.

First gate isolation regions 242a are formed through portions of the first gate structures 240a. The bottom level bi-layer comprises a central dielectric layer 255a and liner dielectric layer 255b. The first gate isolation regions 242a and bi-layer comprising the central dielectric layer 255a and liner dielectric layer 255b divide the first gate structures 240a into gate regions (e.g., gate regions I and II).

Like the semiconductor structure 100-3, the semiconductor structure 200 includes the first ILD layer 230 on top of first gate structures 240a. A top level of transistors similar to the bottom level of transistors is formed on the first ILD layer 230, except that the top level of transistors is not aligned with the bottom level of transistors (e.g., is staggered with respect the bottom level of transistors). The upper transistors include a plurality of second channel layers 207b alternately stacked with and surrounded by second gate structures 240b. As can be seen the first and second channel layers 207a and 207b align with the gate cut portions in the opposing device level.

Like with the first gate structures 240a, portions of the second gate structures 240b are removed where gate isolation regions (also referred to herein as “gate cut portions”) are to be formed. Second gate isolation regions 242b are formed through portions of the second gate structures 240b over the first channel layers 207a. The top level bi-layer comprises a central dielectric layer 245a and liner dielectric layer 245b. The second gate isolation regions 242b and bi-layer comprising the central dielectric layer 245a and liner dielectric layer 245b divide the second gate structures 240b into gate regions (e.g., gate regions III and IV).

Referring to FIG. 27, the central dielectric layer 245a and underlying portions of the first ILD layer 230 are etched to form an opening exposing a top surface of an underlying first gate structure 240a. In order to form a top level conductive via 247, metal is deposited to fill in the opening, followed by a CMP process. As can be seen in the orientation in FIG. 27, the bottom surface of the top level conductive via 247 lands on and contacts the top surface of the underlying first gate structure 240a. Portions of the liner dielectric layer 245b and of an adjacent second gate structure 240b are removed to create an opening where a top level contact portion 249 is formed. In order to form the top level contact portion 249, metal is deposited to fill in the opening, followed by a CMP process. The top level contact portion 249 forms a metal strap that provides a metal connection of an adjacent gate region to a gate cut portion.

Additional ILD material is deposited to form a second ILD layer 231 on top of the second gate structures 240b, the second gate isolation regions 242b, the top level contact portion 249, the top level conductive via 247 and the liner dielectric layer 245b. Then, a frontside gate contact 262, which can be the same as or similar to the first frontside gate contact 162-1, is formed in the second ILD layer 231. As can be seen, the frontside gate contact 262 lands on and contacts the top level conductive via 247 (and/or top level contact portion 249, or the second gate structure 240b in gate region III. depending on a location of the frontside gate contact 262).

Frontside BEOL interconnects 265 are formed on the second ILD layer 231 and are connected to the frontside gate contact 262 through a plurality of wires. As can be understood, a gate voltage from the frontside gate contact 262 can be delivered to the second gate structure 240b of gate region III and to the first gate structure 240a of gate region I through the top level contact portion 249 and the top level conductive via 247, which contacts a top surface of the first gate structure 240a of gate region I due to the staggered configuration. In the semiconductor structure 200, the top level contact portion 249 and the top level conductive via 247 are electrically isolated from the second gate structure 240b of gate region IV by the liner dielectric layer 245b and are electrically isolated from the first gate structure 240a of gate region II by first ILD layer 230 and the liner dielectric layer 255b. The liner dielectric layer 245b is disposed on sides of the top level conductive via 247 between the top level conductive via 247 and the adjacent second gate structures 240b. The second gate structure 240b of gate region III and the first gate structure 240a of gate region I are electrically connected to each other through the top level contact portion 249 and the top level conductive via 247.

The top level conductive via 247 is disposed through the liner dielectric layer 245b, and through the first ILD layer 230 to land on the top surface of the first gate structure 240a of gate region I. The top level contact portion 249 extends perpendicularly from a top end of the top level conductive via 247 into the second gate structure 240b of gate region III.

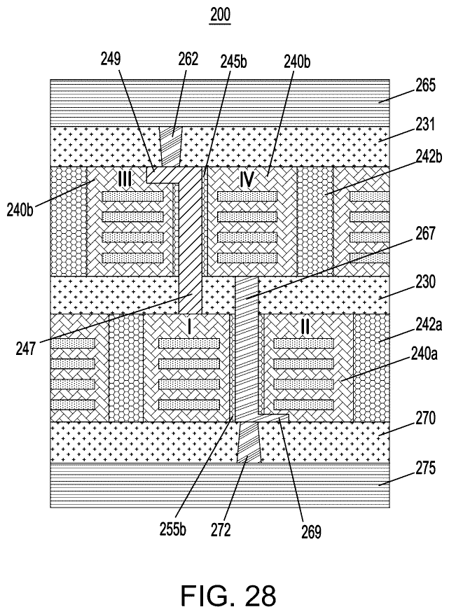

Referring to FIG. 28, similar to the semiconductor structure 100-3, using a carrier wafer (not shown), the semiconductor structure 200 may be “flipped” (e.g., rotated 180 degrees) so that the structure is inverted. In addition, the first semiconductor substrate 201, etch stop layer 202, second semiconductor substrate 203 and portions of the isolation regions 204 are removed from the backside of the semiconductor structure 200.

The central dielectric layer 255a and underlying portions of the first ILD layer 230 are etched from the backside of the semiconductor structure 200 to form an opening exposing a bottom surface of the second gate structure 240b of gate region IV. In order to form a bottom level conductive via 267, metal is deposited to fill in the opening, followed by a CMP process. As can be seen in the orientation in FIG. 28, the top surface of the bottom level conductive via 267 lands on and contacts the bottom surface of the overlying second gate structure 240b of gate region IV. Portions of the liner dielectric layer 255b and of an adjacent first gate structure 240a are removed to create an opening where a bottom level contact portion 269 is formed. In order to form the bottom level contact portion 269, metal is deposited to fill in the opening, followed by a CMP process. The bottom level contact portion 269 forms a metal strap that provides a metal connection of an adjacent gate region to a gate cut portion.

Additional ILD material is deposited to form a backside ILD layer 270 on the first gate structures 240a, the first gate isolation regions 242a, the bottom level contact portion 269, the bottom level conductive via 267 and the liner dielectric layer 255b. Then, a backside gate contact 272, which can be the same as or similar to the backside gate contact 172, is formed in the backside ILD layer 270. As can be seen, the backside gate contact 272 lands on and contacts the bottom level conductive via 267 (and/or bottom level contact portion 269 depending on a location of the backside gate contact 272).

Backside BEOL interconnects 275 are formed on the backside ILD layer 270 and are connected to the backside gate contact 272 through a plurality of wires. As can be understood, a gate voltage from the backside gate contact 272 can be delivered to the first gate structure 240a of gate region II and to the second gate structure 240b of gate region IV through the bottom level contact portion 269 and the bottom level conductive via 267, which contacts a bottom surface of the second gate structure 240b of gate region IV due to the staggered configuration. In the semiconductor structure 200, the bottom level contact portion 269 and the bottom level conductive via 267 are electrically isolated from the first gate structure 240a of gate region I by the liner dielectric layer 255b and are electrically isolated from the second gate structure 240b of gate region III by first ILD layer 230 and the liner dielectric layer 245b. The liner dielectric layer 255b is disposed on sides of the bottom level conductive via 267 between the bottom level conductive via 267 and the adjacent first gate structures 240a. The second gate structure 240b of gate region IV and the first gate structure 240a of gate region II are electrically connected to each other through the bottom level contact portion 269 and the bottom level conductive via 267.

The bottom level conductive via 267 is disposed through the liner dielectric layer 255b, and through the first ILD layer 230 to land on the bottom surface of the second gate structure 240b of gate region IV. The bottom level contact portion 269 extends perpendicularly from a bottom end of the bottom level conductive via 267 into the first gate structure 240a of gate region II.

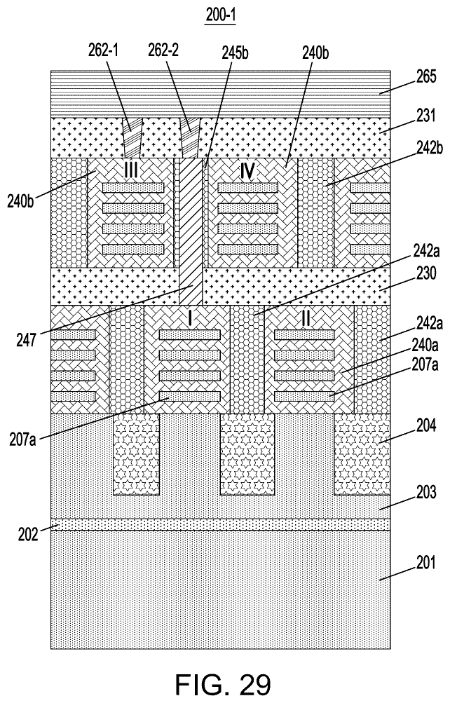

Referring to FIG. 29, a semiconductor structure 200-1 is similar to the semiconductor structure 200 in FIG. 27, except that in the semiconductor structure 200-1, there is no top level contact portion 249. Instead, in the semiconductor structure 200-1, a first frontside gate contact 262-1 contacts the second gate structure 240b of gate region III, and the second gate structure 240b of gate region III is electrically isolated from the top level conductive via 247 by the liner dielectric layer 245b. A second frontside gate contact 262-2 contacts the top level conductive via 247. The top level conductive via 247, which lands on and contacts a top surface of the first gate structure 240a of gate region I, electrically connects the second frontside gate contact 262-2 to the first gate structure 240a of gate region I.

It is to be understood that, in illustrative embodiments, although shown as single dielectric layers, each of the first gate isolation regions 142a/242a and second gate isolation regions 142b/242b can be bi-layer dielectric layers like the combination of central and liner dielectric layers 145a and 145b, 155a and 155b, 245a and 245b, and 255a and 255b.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming interconnecting structures for stacked FETs. The illustrative embodiments include stacked FETs with at least one gate-cut portion including a metal via within the gate-cut portion, wherein the gate-cut portion includes sidewalls of dielectric material separating the via from the metal gates. At least one adjacent metal gate is electrically connected to the metal via through a metal contact extending from the via. Advantageously, the illustrative embodiments provide a solution to issues with gate merging in sequential integration of stacked FETs. As an additional advantage, the embodiments provide top, bottom, adjacent and/or cross-gate merging schemes that reduce the use of external routing through metallization layers.

In one embodiment, a semiconductor device comprises a first transistor structure comprising a first gate region and a second gate region, a first dielectric layer disposed between the first gate region and the second gate region, a second transistor structure stacked on the first transistor structure and comprising a third gate region and a fourth gate region, and a second dielectric layer disposed between the third gate region and the fourth gate region. A conductive via is disposed through at least one of the first dielectric layer and the second dielectric layer, wherein at least one of the first gate region and the second gate region are electrically connected to at least one of the third gate region and the fourth gate region by the conductive via.

The first dielectric layer may be disposed on sides of the conductive via between the first gate region and the second gate region and the conductive via. The second dielectric layer may be disposed on sides of the conductive via between the third gate region and the fourth gate region and the conductive via.

The semiconductor device may further comprise a conductive contact portion that extends from an end of the conductive via into one of the first gate region, the second gate region, the third gate region and the fourth gate region. The conductive contact portion may extend perpendicularly from the end of the conductive via.

The conductive via may be connected to a power source at one of a frontside and a backside of the semiconductor device. The first transistor structure may be aligned with the second transistor structure. Alternatively, the first transistor structure may be staggered with respect to the second transistor structure, wherein the conductive via is disposed through the first dielectric layer and contacts a bottom surface of one of the third gate region and the fourth gate region. The conductive via may be disposed through the second dielectric layer and contact a top surface of one of the first gate region and the second gate region.

The conductive via can be disposed through the first dielectric layer and the second dielectric layer. The semiconductor device of may further comprise a first conductive contact portion that extends from a first end of the conductive via into one of the first gate region and the second gate region, and a second conductive contact portion that extends from a second end of the conductive via into one of the third gate region and the fourth gate region.

The conductive via may be disposed through the second dielectric layer into a portion of the first dielectric layer, wherein a first conductive contact portion extends from a first end of the conductive via into one of the first gate region and the second gate region, and a second conductive contact portion extends from a second end of the conductive via into one of the third gate region and the fourth gate region.

In another embodiment, a semiconductor device includes a first device layer comprising a first dielectric layer disposed between a first gate region and a second gate region, a second device layer stacked on the first device layer and comprising a second dielectric layer disposed between a third gate region and a fourth gate region, and a conductive via disposed in at least one of the first dielectric layer and the second dielectric layer. At least one of the first gate region and the second gate region are electrically connected to at least one of the third gate region and the fourth gate region through the conductive via.

The semiconductor device may further comprise a first conductive contact portion that extends perpendicularly from a first end of the conductive via to contact one of the first gate region and the second gate region, and a second conductive contact portion that extends perpendicularly from a second end of the conductive via to contact one of the third gate region and the fourth gate region. The conductive via may be disposed through the second dielectric layer and contact a top surface of one of the first gate region and the second gate region.

In another embodiment, a semiconductor device includes a first dielectric layer disposed between a first set of two gate regions, a second dielectric layer disposed between a second set of two gate regions, wherein the second set of two gate regions are stacked on the first set of two gate regions, and a contact structure disposed in at least one of the first dielectric layer and the second dielectric layer. At least one gate region of the first set of two gate regions is electrically connected to at least one other gate region of the second set of two gate regions through the contact structure.

The semiconductor device may further comprise a first conductive contact portion disposed between a first part of the contact structure and the at least one gate region, wherein the first conductive contact portion contacts the first part of the conductive structure and contacts the at least one gate region, and a second conductive contact portion disposed between a second part of the conductive structure and the at least one other gate region, wherein the second conductive contact portion contacts the second part of the conductive structure and contacts the at least one other gate region. The contact structure may be disposed through one of the first dielectric layer and the second dielectric layer and in at least a portion of the other of the first dielectric layer and the second dielectric layer.

These and other features and advantages of embodiments described herein will become more apparent from the accompanying drawings and the following detailed description.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor structure comprising a first gate region and a second gate region;
a first dielectric layer disposed between the first gate region and the second gate region;
a second transistor structure stacked on the first transistor structure and comprising a third gate region and a fourth gate region;
a second dielectric layer disposed between the third gate region and the fourth gate region; and
a conductive via disposed through at least one of the first dielectric layer and the second dielectric layer;
wherein at least one of the first gate region and the second gate region are electrically connected to at least one of the third gate region and the fourth gate region by the conductive via.

2. The semiconductor device of claim 1, wherein the first dielectric layer is disposed on sides of the conductive via between the first gate region and the second gate region and the conductive via.

3. The semiconductor device of claim 1, wherein the second dielectric layer is disposed on sides of the conductive via between the third gate region and the fourth gate region and the conductive via.

4. The semiconductor device of claim 1, further comprising a conductive contact portion that extends from an end of the conductive via into one of the first gate region, the second gate region, the third gate region and the fourth gate region.

5. The semiconductor device of claim 4, wherein the conductive contact portion extends perpendicularly from the end of the conductive via.

6. The semiconductor device of claim 1, wherein the conductive via is connected to a power source at one of a frontside and a backside of the semiconductor device.

7. The semiconductor device of claim 1, wherein the first transistor structure is aligned with the second transistor structure.

8. The semiconductor device of claim 1, wherein the first transistor structure is staggered with respect to the second transistor structure.

9. The semiconductor device of claim 8, wherein the conductive via is disposed through the first dielectric layer and contacts a bottom surface of one of the third gate region and the fourth gate region.

10. The semiconductor device of claim 8, wherein the conductive via is disposed through the second dielectric layer and contacts a top surface of one of the first gate region and the second gate region.

11. The semiconductor device of claim 1, wherein the conductive via is disposed through the first dielectric layer and the second dielectric layer.

12. The semiconductor device of claim 11, further comprising:
a first conductive contact portion that extends from a first end of the conductive via into one of the first gate region and the second gate region; and
a second conductive contact portion that extends from a second end of the conductive via into one of the third gate region and the fourth gate region.

13. The semiconductor device of claim 1, wherein the conductive via is disposed through the second dielectric layer into a portion of the first dielectric layer.

14. The semiconductor device of claim 13, further comprising:
a first conductive contact portion that extends from a first end of the conductive via into one of the first gate region and the second gate region; and
a second conductive contact portion that extends from a second end of the conductive via into one of the third gate region and the fourth gate region.

15. A semiconductor device comprising:
a first device layer comprising a first dielectric layer disposed between a first gate region and a second gate region;
a second device layer stacked on the first device layer and comprising a second dielectric layer disposed between a third gate region and a fourth gate region; and
a conductive via disposed in at least one of the first dielectric layer and the second dielectric layer;
wherein at least one of the first gate region and the second gate region are electrically connected to at least one of the third gate region and the fourth gate region through the conductive via.

16. The semiconductor device of claim 15, further comprising:
a first conductive contact portion that extends perpendicularly from a first end of the conductive via to contact one of the first gate region and the second gate region; and
a second conductive contact portion that extends perpendicularly from a second end of the conductive via to contact one of the third gate region and the fourth gate region.

17. The semiconductor device of claim 15, wherein the conductive via is disposed through the second dielectric layer and contacts a top surface of one of the first gate region and the second gate region.

18. A semiconductor device comprising:
a first dielectric layer disposed between a first set of two gate regions;
a second dielectric layer disposed between a second set of two gate regions, wherein the second set of two gate regions are stacked on the first set of two gate regions; and
a contact structure disposed in at least one of the first dielectric layer and the second dielectric layer;
wherein at least one gate region of the first set of two gate regions is electrically connected to at least one other gate region of the second set of two gate regions through the contact structure.

19. The semiconductor device of claim 18, further comprising:
a first conductive contact portion disposed between a first part of the contact structure and the at least one gate region, wherein the first conductive contact portion contacts the first part of the contact structure and contacts the at least one gate region; and
a second conductive contact portion disposed between a second part of the contact structure and the at least one other gate region, wherein the second conductive contact portion contacts the second part of the contact structure and contacts the at least one other gate region.

20. The semiconductor device of claim 18, wherein the contact structure is disposed through one of the first dielectric layer and the second dielectric layer and in at least a portion of the other of the first dielectric layer and the second dielectric layer.
